(19) United States
(12) Patent Application Publication
(10) Pub. No.: US 2025/0194320 A1
(43) Pub. Date: Jun. 12, 2025

(54) METHOD FOR PRODUCING AN OPTOELECTRONIC COMPONENT AND OPTOELECTRONIC COMPONENT

(71) Applicant: ams-OSRAM International GmbH, Regensburg (DE)

(72) Inventors: Bernd Böhm, Obertraubling (DE); Markus Klein, Regensburg (DE); Matthias Bruckschloegl, Regensburg (DE); Sebastian Wittmann, Regenstauf (DE)

(21) Appl. No.: 18/844,715

(22) PCT Filed: Mar. 22, 2023
(86) PCT No.: PCT/EP2023/057316

§ 371 Date: Sep. 6, 2024

(30) Foreign Application Priority Data
Apr. 5, 2022 (DE) 102022108133.8

(51) Int. Cl. H10H 29/03; H10H 29/01

(52) U.S. Cl. CPC H10H 29/03; H10H 29/0361; H10H 29/0363

(57) ABSTRACT

In an embodiment a method includes providing a carrier, applying a plurality of semiconductor chips to the carrier, the semiconductor chips being spaced apart from one another such that cavities are formed between the semiconductor chips, introducing a photo-exposable material, at least the cavities being filled with the photo-exposable material, exposing the photo-exposable material, wherein parts of the photo-exposable material, which are downstream of the semiconductor chips with respect to an exposure remain unexposed, removing unexposed parts of the photo-exposable material, wherein recesses are formed, applying a functional layer to the semiconductor chips, and removing the exposed photo-exposable material.

### CROSS-REFERENCE TO RELATED APPLICATIONS

This patent application is a national phase filing under section 371 of PCT/EP2023/057316, filed Mar. 22, 2023, which claims the priority of German patent application 102022108133.8, filed Apr. 5, 2022, each of which is incorporated herein by reference in its entirety.

### TECHNICAL FIELD

A method for producing an optoelectronic component is disclosed. Furthermore, an optoelectronic component is disclosed.

### SUMMARY

Embodiments provide a method for producing an optoelectronic component with improved properties. Further embodiments provide an optoelectronic component with improved properties.

Optoelectronic components can have at least one semiconductor chip that emits electromagnetic radiation in a specific wavelength range. For example, the optoelectronic component is a semiconductor laser component or a light-emitting diode.

According to one embodiment of the method for producing an optoelectronic component, a carrier is provided. The carrier is in particular a carrier for optoelectronic components and is used for mechanical fastening and stability. The carrier is designed, for example, as a flat and planar plate with a main direction of extension.

The carrier can be formed as a substrate, wafer or artificial wafer. The carrier can have any shape, for example the carrier can be angular, in particular rectangular or square, round or oval. A dimension of the carrier can also vary. If the carrier is rectangular, it can have a dimension of 125 mm×70 mm. If the carrier is square, it can have a dimension of 4 inches×4 inches. If the carrier is round, the diameter can be 4 inches, 150 mm or 200 mm. Preferably, a thickness of the carrier is less than 1000 micrometers. A thickness of the carrier is particularly preferably in a range between 500 micrometers and 1000 micrometers.

For example, the carrier comprises glass or a polymer as a material. A particularly preferred carrier is a silicon wafer, a circuit board (PCB) made of, for example, fiber-reinforced plastic or a stainless steel plate.

According to at least one embodiment of the method, a plurality of semiconductor chips is applied to the carrier. The plurality of semiconductor chips is, for example, a plurality of light emitting diode chips or a plurality of laser diode chips. Preferably, the plurality of semiconductor chips has an epitaxially grown semiconductor layer sequence with an active zone that is set up to generate primary radiation. For this purpose, the active zone has, for example, a pn junction, a double heterostructure, a single quantum well structure or, in particular, preferably a multiple quantum well structure. Preferably, each of the plurality of semiconductor chips emits a primary radiation of a first wavelength range from a radiation exit surface. In particular, during operation, the plurality of semiconductor chips emits primary radiation from the ultraviolet spectral range and/or from the visible spectral range, particularly preferably from the blue spectral range.

The semiconductor chips can also be a side-emitting semiconductor chip. In the case of side-emitting semiconductor chips, primary radiation is emitted from at least one side surface of the semiconductor chip. In other words, in the case of side-emitting semiconductor chips, the radiation exit surface is transverse or perpendicular to the main extension direction. In particular, it is possible for the primary radiation of a side-emitting semiconductor chip to emerge exclusively through at least one side surface and not through a cover surface and/or a bottom surface. The primary radiation can emerge exclusively through exactly one side surface, at least two side surfaces or all side surfaces of the semiconductor chip.

The semiconductor chips preferably have a thickness of more than 3 μm. It is particularly preferred that the semiconductor chips have a thickness of more than 4 μm. For example, the semiconductor chips have a thickness of between 5 μm and 120 μm inclusive. The thickness corresponds to a vertical extension which is arranged transversely to the main direction of extension.

The plurality of semiconductor chips is preferably arranged on the carrier in a common area, in particular plane. The carrier comprises a first side. The semiconductor chips are preferably arranged on the first side. Applying the plurality of semiconductor chips to the carrier leads to cost advantages and to an improvement in the process speed.

According to at least one embodiment of the method, the plurality of semiconductor chips is applied spaced apart from one another in such a way that cavities are formed between the semiconductor chips. This means that a cavity is formed between two neighboring semiconductor chips. The cavities are empty spaces. The cavities extend in particular as far as the carrier. A width of the cavities, which extends between two semiconductor chips, is preferably in a range between 50 μm inclusive and 200 μm inclusive. The width of the cavities corresponds to a lateral extension which is arranged parallel to the main extension direction. In other words, the semiconductor chips on the carrier have a spacing of between 50 μm inclusive and 200 μm inclusive. The distance between the individual semiconductor chips to each other can vary. A height of the cavities, which corresponds to a vertical extension, is preferably in a range of between 5 μm inclusive and 120 μm inclusive. The height of the cavities is particularly preferably between 5 μm inclusive and 100 μm inclusive. The height of the cavities corresponds in particular to the thickness of the semiconductor chips.

According to at least one embodiment of the method, a photo-exposable material is introduced. The photo-exposable material is formed, for example, from a polymer which has a photoinitiator. Photo-exposable materials are, for example, polymethylmetacrylate, novolak or polymethylglutarimide or epoxy resins, for example SU-8. In addition, solvents such as cyclopentanone or gamma-butyrolactone can also be a component of the photo-exposable material.

For example, when the polymer is irradiated or exposed to electromagnetic radiation of a certain wavelength, the photoinitiator causes a crosslinking reaction and thus causes the polymer to cure. Alternatively, the photoinitiator causes the bonds to dissolve when the polymer is irradiated with electromagnetic radiation, thus dissolving the polymer. A common field of application for the photo-exposable material is, for example, in lithography. Preferably, the photo-exposable material is a photoresist.

According to at least one embodiment, at least the cavities are filled with the photo-exposable material. In particular, the photo-exposable material is formed as a layer or is introduced into the cavities in liquid form. Preferably, the photo-exposable material can be introduced into the cavities in several steps. For example, the photo-exposable material is applied using the spin coating method. Preferably, thin and uniform layers of the photo-exposable material are introduced into the cavities. For example, the photo-exposable material is additionally arranged on the semiconductor chips. Furthermore, the photo-exposable material can be arranged between the semiconductor chips and the carrier. The photo-exposable material is particularly preferably introduced directly into the cavities by spray coating and/or by means of an inkjet method. In particular, the spray coating is applied over a large area. With a favorably selected dispensing volume and viscosity, the filling level of the cavities can be controlled without applying photo-exposable material to the semiconductor chips.

According to at least one embodiment, the photo-exposable material is exposed, wherein parts of the photo-exposable material that are downstream of the semiconductor chips with respect to the exposure remain unexposed. Exposure is preferably carried out with a UV light source, for example at 365 nm or with an LDI laser (Laser Diode Illuminator), for example at 355 nm. The advantage of using a laser is that the laser has a very parallel beam path, which reduces laterally scattered light. The beam path of the laser is perpendicular to the main extension direction of the carrier. This enables deeper penetration into the photo-exposable material, allowing complete exposure of the photo-exposable material, for example in the cavities. The duration of the exposure depends on the thickness of the photo-exposable material to be exposed and on the light source.

During exposure, the solubility of the photo-exposable material is changed locally by the light source, for example an ultraviolet light source, and an exposure mask. The semiconductor chips are the preferred exposure mask here. This means that the photo-exposable material, which is downstream of the semiconductor chips in terms of exposure, remains unexposed. The unexposed part of the photo-exposable material is therefore precisely limited to or matched to the semiconductor chip surface. This has the advantage that the exact determination of the semiconductor chip position on the carrier is irrelevant. The exposure is preferably followed by a temperature step. This serves to cure the photo-exposable material in addition to the exposure.

The photo-exposable material, which is located in the cavities, is preferably exposed. This preferably forms a cured photo-exposable material.

According to at least one embodiment of the method, the unexposed parts of the photo-exposable material are removed, wherein recesses are formed. The recesses are preferably located between two adjacent cavities. In particular, the recesses have a depth extending from the upper edge of the photo-exposed material in the cavities towards a side of the semiconductor chip facing away from the carrier. The upper edge of the photo-exposable material is facing away from the carrier. In particular, the recess is arranged on the semiconductor chip. “On the semiconductor chip” means here and in the following on the side of the semiconductor chip facing away from the carrier.

The unexposed part of the photo-exposable material is preferably removed using a developer liquid. A developer liquid is, for example, an alkaline liquid or an alkaline medium.

According to at least one embodiment of the method, a functional layer is applied to the semiconductor chips. In other words, the functional layer is applied to the side of the semiconductor chips facing away from the carrier. The functional layer is applied, for example, by doctoring, sputtering, vapor deposition or spray coating. The functional layer can have a thickness of up to 20 μm. The thickness of the functional layer depends, for example, on the depth of the recess.

For example, the functional layer can convert primary radiation into secondary radiation. Particles can also be incorporated into the functional layer. For example, the functional layer is designed as a reflection layer, a conversion layer or a combination thereof. If the functional layer is designed as a reflective layer, it has the property of reflecting primary radiation, preferably emitted by the semiconductor chips.

According to at least one embodiment, the exposed photo-exposable material is removed. The exposed photo-exposable material is preferably removed in a solvent and/or in an alkaline medium. Optionally, this process is also supported by high pressure. This process is known as wet chemical stripping. The exposed photo-exposable material can also be removed in a plasma asher. Here, a microwave-excited oxygen plasma is used to etch away the photoresist isotropically. This process is known as ashing. The exposed photo-exposable material is preferably removed in the cavities.

According to at least one embodiment of the method for producing an optoelectronic component, a carrier is provided. A plurality of semiconductor chips is then applied to the carrier, the semiconductor chips being applied spaced apart from one another in such a way that cavities are formed between the semiconductor chips. A photo-exposable material is introduced, wherein at least the cavities are filled with the photo-exposable material. The photo-exposable material is then exposed, with parts of the photo-exposable material that are downstream of the semiconductor chips with respect to the exposure remaining unexposed. Afterwards, unexposed parts of the photo-exposable material are removed, forming recesses. A functional layer is applied to the semiconductor chips and the exposed photo-exposable material is removed.

According to at least one embodiment, the method for producing an optoelectronic component is carried out according to the sequence described.

One idea of the method for producing an optoelectronic component is to apply a functional layer to a plurality of radiation-emitting semiconductor chips in order to provide a cost-effective and simplified method for producing optoelectronic components. Complex, precise position measurement and position-dependent (adjusted) exposure derived from this, for example exposure via laser direct imaging (LDI), are no longer necessary. In addition, alignment structures that offer sufficiently good contrast and visibility are no longer necessary.

According to at least one embodiment of the method, the recesses are at least partially filled by the functional layer. Preferably, the recesses are completely filled by the functional layer. The depth of the recesses can thus advantageously be used to adjust the thickness of the functional layer. Advantageously, the depth of the recesses can be controlled by the thickness of the photo-exposable material used in the recesses.

According to at least one embodiment of the method, the exposure is carried out selectively. This has the advantage that a specific area can be selectively exposed.

According to at least one embodiment of the method, the exposure is carried out over the entire surface and in a self-adjusting manner. The exposure is carried out over the entire surface, for example by means of flood exposure. The photo-exposable material is exposed in a self-adjusting manner. One advantage of this is that the two time-consuming steps of AOI and LDI (AOI=automatic optical inspection, LDI=laser direct imaging) are no longer necessary.

The exposure over the entire surface can be carried out as the semiconductor chips themselves are used to define the later unexposed parts of the photo-exposable material. This advantageously reduces the complexity of the process chain. In particular, no special requirements for overlay and dimensional accuracy have to be met in case of exposure over the entire surface. The exact position of the semiconductor chips on the carrier is therefore irrelevant.

According to at least one embodiment of the method, a negative resist is used as the photo-exposable material. The negative resist polymerizes through exposure and a subsequent heating step. After development, the exposed areas remain. Polymethyl metacrylate, novolak, polymethyl glutarimide, epoxy resins, for example SU-8 or combinations thereof, are preferably used as the negative resist. Positive image reversal resists can also be used as photo-exposable materials.

According to at least one embodiment, the photo-exposable material is a dry resist and/or a wet resist. In the case of a wet resist, the wet resist is preferably applied to the carrier and centrifuged in a processing chamber. The final thickness of the wet resist can be specifically adjusted via the rotational speed during spin coating.

In particular, the dry resist is applied to the carrier or to the semiconductor chips in a predetermined thickness. For example, the dry resist is deposited on a carrier film with a certain thickness and is then preferably deposited onto the semiconductor chips or onto the carrier and removed from the carrier film under vacuum and by raising the temperature. One advantage of the dry resist is that only small inclusions are formed in the dry resist and thus a uniform layer can be formed. In contrast, the surface of the wet resist can be wavy, which can impair the light extraction of the optoelectronic component. One advantage of the wet resist is that it can flow better into cavities or recesses.

According to at least one further embodiment, the photo-exposable material is applied by means of a curtain coating. The advantage of curtain coating is that the photo-exposable material can be applied particularly evenly. In addition, the photo-exposable material can be applied with very little waste. Multilayer application of the photo-exposable material is also possible. In addition, the thickness of the photo-exposable material can be adjusted particularly well by the curtain coating.

According to at least one embodiment of the method, the functional layer has a thickness and the recess has a depth, wherein the thickness of the functional layer corresponds at most to the depth of the recess. In other words, this means that the functional layer and the recess each have a vertical extent, wherein the vertical extent of the functional layer corresponds at most to the vertical extent of the recess. Vertical in the following means transverse or perpendicular to the main direction of extension. As a result, the thickness of the functional layer can be determined with advantage by the photo-exposable material in the recesses or by the photo-exposable material in the cavities.

According to at least one embodiment, prior to the applying the plurality of semiconductor chips, a part of the photo-exposable material is applied between the carrier and the semiconductor chips and the exposure is carried out from the side of the semiconductor chips which is free of the photo-exposable material. The photo-exposable material is preferably applied between the carrier and the semiconductor chip in the form of a layer. It is particularly preferable for the layer to be applied contiguously. The photo-exposable material is in particular a photoresist layer. The photo-exposable material preferably has a thickness of between 0.5 μm inclusive and 100 μm inclusive. For example, the photo-exposable material has a thickness of between 5 μm inclusive and 100 μm inclusive. In this case, the semiconductor chips serve as an exposure mask and the part of the photo-exposable material arranged between the semiconductor chip and the carrier remains unexposed. Advantageously, the thickness of the photo-exposable material between the semiconductor chips and the carrier can be used to determine the depth of the recesses. The depth of the recesses in turn determines the thickness of the functional layer.

According to at least one embodiment, the part of the photo-exposable material which is located between the carrier and the semiconductor chip is a wet resist or dry resist and the photo-exposable material which is located in the cavities is a wet resist. The thickness of the wet resist can be determined via the rotational speed during the spin coating process, while the thickness of the dry resist is already predetermined. Alternatively, the wet resist can be selectively applied into the cavities using an inkjet method. One advantage of using a dry resist as a layer between the semiconductor chips and the carrier is that the semiconductor chips can sink into the dry resist only with difficulty. The wet resist is particularly suitable for filling the cavities, as it has better flow behavior than a dry resist and can therefore be introduced into the cavities more easily. If the photo-exposable material between the carrier and the semiconductor chips is about 1 μm thick, for example, a wet resist is preferably used and if the photo-exposable material between the carrier and the semiconductor chips is about 10 μm thick, for example, a dry resist is used. The dry resist and the wet resist are preferably the same material. For example, AZ15nXT from MERCK is used as the wet resist and WBR2075 from DuPont is used as the dry resist.

According to at least one embodiment of the method, an auxiliary carrier is arranged on the side of the semiconductor chips facing away from the carrier after exposure and the carrier is removed. As a result, the semiconductor chips are now in direct contact, preferably with the auxiliary carrier. This process step is also referred to as re-taping or re-bonding. By re-taping, the part of the photo-exposable material that is unexposed is uncovered. This allows the unexposed part of the photo-exposable material to be removed by developing. The functional layer can then be applied to the uncovered semiconductor chips. The auxiliary carrier preferably has the same properties as the carrier.

According to at least one embodiment, prior to applying of the plurality of semiconductor chips, a part of the photo-exposable material is applied between the carrier and the semiconductor chips and the exposure is carried out from the side of the semiconductor chips which is free of the photo-exposable material. The part of the photo-exposable material located between the carrier and the semiconductor chips is in particular a dry resist and the photo-exposable material located in the cavities is a wet resist. After exposure, an auxiliary carrier is arranged on the side of the semiconductor chips facing away from the carrier and the carrier is removed.

According to at least one embodiment, the carrier is designed to be radiation permeable. Radiation permeable means that it is permeable to radiation, i.e. that the carrier is preferably transparent. Preferably, the carrier is designed to be radiation permeable for a wavelength of exposure, for example for a UV light source. This is advantageous if the exposure takes place through the carrier.

According to at least one embodiment, an adhesive layer is arranged between the carrier and the plurality of semiconductor chips. The adhesive layer is preferably transparent or radiation permeable for the exposure wavelength. The adhesive layer is applied thinly to the carrier and then the plurality of semiconductor chips is arranged on the adhesive layer.

According to at least one embodiment, an anti-reflective layer is arranged between the carrier and the adhesive layer or between the adhesive layer and the plurality of semiconductor chips. The anti-reflective layer preferably serves to minimize lateral scattering from the optoelectronic component.

According to at least one embodiment of the method, the exposure takes place through the carrier, so that the part of the photo-exposable material which is located on the semiconductor chips remains unexposed. Preferably, the exposure takes place through the carrier and through the adhesive layer. Preferably, the semiconductor chips serve as an exposure mask for the exposure and thus the part of the photo-exposable material that is located on the side of the semiconductor chip that is not directly exposed remains unexposed.

According to at least one embodiment of the method, the carrier is designed to be radiation permeable and an adhesive layer is arranged between the carrier and the plurality of semiconductor chips, which is also radiation permeable. The photo-exposable material is applied to the semiconductor chips and into the cavities in a single step.

Optionally, in a two-step method, the photo-exposable material is first introduced into the cavities in the form of a wet resist so that the wet resist is flush with the top of the semiconductor chip. In a second step, the photo-exposable material in the form of a dry resist is applied to the semiconductor chip and to the photo-exposable material in the cavities as a layer. The wet resist and the dry resist preferably have the same material. The exposure takes place through the carrier and through the adhesive layer, so that the part of the photo-exposable material on the semiconductor chips remains unexposed. The two-step method is preferably used for semiconductor chips with a thickness of 5 μm to 120 μm. The application of the wet resist depends in particular on the thickness of the semiconductor chips. The thinner the semiconductor chip, the more likely it is that the photo-exposable material will be applied using spin coating. For thicker semiconductor chips, the photo-exposable material is preferably applied using an inkjet method.

According to at least one embodiment of the method, after removal of the exposed photo-exposable material, the semiconductor chips are singulated to generate optoelectronic components. Singulating means that the semiconductor chips with the respective functional layer are removed from the carrier or the adhesive layer and fixed in a desired location. Alternatively, the carrier is sawn through, etched, broken or separated by laser dicing, for example, so that a part of the carrier, the semiconductor chip and the functional layer each form an optoelectronic component. This means that saw marks can only occur on the carrier. The side surfaces of the functional layer and the semiconductor chip advantageously remain free of traces of a separation process.

An optoelectronic component is further disclosed. In particular, the method described for producing an optoelectronic component can be used to produce an optoelectronic component as described herein. In other words, all features disclosed for the method of producing an optoelectronic component are also disclosed for the optoelectronic component and vice versa.

According to at least one embodiment, the optoelectronic component has a semiconductor chip which emits primary radiation of a first wavelength range during operation. The semiconductor chip preferably has a radiation exit surface. The radiation exit surface can be parallel to the main extension direction or it can be arranged on the side surface of the semiconductor chip. This means that the radiation exit surface can be parallel to the main extension direction or transverse to the main extension direction. If the radiation exit surface is arranged on the side surface of the semiconductor chip, it is a side-emitting semiconductor chip.

According to at least one embodiment, the optoelectronic component has a functional layer arranged on the semiconductor chip. The functional layer is preferably in direct contact with the semiconductor chip. This means that no other layer is arranged between the semiconductor chip and the functional layer. The functional layer is described, for example, as a conversion layer, absorption layer or reflection layer.

According to at least one embodiment of the optoelectronic component, side surfaces of the functional layer and the semiconductor chip are flush with each other. The side surfaces are the surfaces of the semiconductor chip and the functional layer that delimit the semiconductor chip and the functional layer in their lateral expansion. In other words, the side surfaces of the functional layer preferably do not protrude beyond the side surfaces of the semiconductor chip in the lateral direction. The side surfaces are preferably free of traces of a singulation process.

According to at least one embodiment of the optoelectronic component, the optoelectronic component comprises a semiconductor chip which emits primary radiation of a first wavelength range during operation, a functional layer which is arranged on the semiconductor chip, and side surfaces of the functional layer and of the semiconductor chip are flush with one another.

According to at least one embodiment, the optoelectronic component comprises a carrier. The carrier can be designed to be radiation permeable.

According to at least one embodiment of the optoelectronic component, the functional layer has a thickness of up to 20 μm.

According to at least one embodiment of the method or the optoelectronic component, the functional layer comprises a conversion layer. The conversion layer is preferably arranged to emit secondary radiation of a second wavelength range. The conversion layer preferably converts the primary radiation of the semiconductor chip into secondary radiation. In particular, the conversion layer is arranged on the radiation exit surface of the semiconductor chip. The conversion layer has, for example, a phosphor and a matrix. The matrix is preferably translucent or transparent for electromagnetic radiation, for example visible light. The phosphor is preferably introduced into the matrix in the form of phosphor particles. The matrix preferably wraps the phosphor particles completely, i.e. the phosphor particles are preferably embedded in the matrix. During operation, the phosphor particles convert the primary radiation of a first wavelength range into secondary radiation of a second wavelength range. The primary radiation is preferably different from the secondary radiation. The phosphor particles embedded in the matrix preferably impart wavelength-converting properties to the conversion layer. For example, the conversion layer with the phosphor particles only partially converts the primary radiation of the semiconductor chip into secondary radiation, while a further part of the primary radiation of the semiconductor chip is transmitted by the conversion layer.

The phosphor is, for example, a ceramic phosphor and/or a quantum dot phosphor. Preferably, the ceramic phosphors are a garnet phosphor. The garnet phosphor is particularly preferably a YAG phosphor with the chemical formula Y₃Al₅O₁₂:Ce₃₊ or a LuAG phosphor with the chemical formula Lu₃Al₅O₁₂:Ce₃₊. Furthermore, the ceramic phosphors can also comprise a nitride phosphor. The nitride phosphors preferably convert blue primary radiation into red secondary radiation. The nitride phosphor can be an alkaline earth silicon nitride, an oxynitride, an aluminum oxynitride, a silicon nitride or a Sialon, for example. For example, the nitride phosphor is (Ca,Sr,Ba)AlSiN₃:Eu₂₊ (CASN).

The ceramic phosphors are particularly preferably selected from the following group:

Ce³⁺ doped garnets such as YAG and LuAG, for example (Y,Lu,Gd,Tb)₃(Al₁₋ₓ,Gaₓ)₅O₁₂:Ce³⁺; Eu²⁺ doped nitrides, for example (Ca,Sr)AlSiN₃:Eu²⁺, Sr(Ca,Sr)Si₂Al₂N₆:Eu²⁺ (SCASN), (Sr,Ca)AlSiN₃*Si₂N₂O:Eu²⁺, (Ca,Ba,Sr)₂Si₅N₈:Eu²⁺, SrLiAl₃N₄:Eu²⁺, SrLi₂Al₂O₂N₂:Eu²⁺; Ce³⁺ doped nitrides, for example (Ca,Sr)Al_{(1-4x/3)}Si₍₁₊ₓ₎N₃:Ce; (x=0.2-0.5); Eu²⁺ doped sulphides, (Ba,Sr,Ca)Si₂O₂N₂:Eu²⁺, SiAIONs, nitrido-orthosilicates (e.g. AE₂₋ₓ₋ₐREₓEuₐSi_{1-y}O_{4-x-2y}Nₓ), orthosilicates (Ba,Sr,Ca)₂SiO₄:Eu²⁺; chlorosilicates (e.g. Ca₈Mg(SiO₄)₄Cl₂:Eu²⁺); Mn⁴⁺ doped fluorides, for example (K,Na)₂(Si,Ti)F₆:Mn⁴⁺; Eu²⁺ or Ce³⁺ doped litho-silicates, such as (Li,Na,K,Rb,Cs)(Li₃SiO₄):E with E as Eu²⁺, Ce³⁺, or (Sr,Li)Li₃AlO₄:Eu²⁺ or SrLi₃AlO₄:Eu²⁺.

Other possible materials for the phosphors include, in particular, the following aluminum-containing and/or silicon-containing phosphor particles:

(Ba_{1-x-y}SrₓCa_{y})SiO₄:Eu²⁺ (0≤x≤1, 0≤y≤1), (Ba_{1-x-y}SrₓCa_{y})₃SiO₅:Eu²⁺ (0≤x≤1, 0≤y≤1), Li₂SrSiO₄:Eu²⁺, oxo-nitrides such as (Ba_{1-x-y}SrₓCa_{y})Si₂O₂N₂:Eu²⁺ (0≤x≤1; 0≤y≤1), SrSiAl₂O₃N₂:Eu²⁺, Ba₄₋ₓCaₓSi₆ON₁₀:Eu²⁺ (0≤x≤1), (Ba₁₋ₓSrₓ)Y₂Si₂Al₂O₂N₅:Eu²⁺ (0≤x≤1), SrₓSi_{(6-y)}Al_{y}O_{y}N_{(8-y)}:Eu²⁺ (0.05≤x0.5; 0.001≤y≤0.5), Ba₃Si₆O₁₂N₂:Eu²⁺, Si_{6-z}Al_{z}O_{z}N_{8-z}:Eu²⁺ (0≤z≤0.42), MₓSi₁₂₋ₘ₋ₙAlₘ₊ₙOₙN₁₆₋ₙ:Eu²⁺ (M=Li, Mg, Ca, Y; x=m/v; v=valency of M, x≤2), MₓSi₁₂₋ₘ₋ₙAlₘ₊ₙOₙN₁₆₋ₙ:Ce³⁺, AE₂₋ₓ₋ₐREₓEuₐSi_{1-y}O_{4-x-2y}Nₓ (AE=Sr, Ba, Ca, Mg; RE=rare earth elements), AE₂₋ₓ₋ₐREₓEuₐSi_{1-y}O_{4-x-2y}Nₓ (AE=Sr, Ba, Ca, Mg; RE=rare earth elements), Ba₃Si₆O₁₂N₂:Eu²⁺ or nitrides such as La₃Si₆N₁₁:Ce³⁺, (Ba_{1-x-y}SrₓCa_{y})₂Si₅N₈:Eu²⁺, (Ca_{1-x-y}SrₓBa_{y})AlSiN₃:Eu²⁺ (0≤x≤1; 0≤y≤1), Sr(Sr₁₋ₓCaₓ)Al₂Si₂N₆:Eu²⁺ (0≤x≤0.2), Sr(Sr₁₋ₓCaₓ)Al₂Si₂N₆:Ce³⁺ (0≤x≤0.2) SrAlSi₄N₇:Eu²⁺, (Ba_{1-x-y}SrₓCa_{y})SiN₂:Eu²⁺ (0≤x≤1; 0≤y≤1), (Ba_{1-x-y}SrₓCa_{y})SiN₂:Ce³⁺ (0≤x≤1; 0≤y≤1), (Sr₁₋ₓCaₓ)LiAl₃N₄:Eu²⁺ (0≤x≤1), (Ba_{1-x-y}SrₓCa_{y})Mg₂Al₂N₄:Eu²⁺ (0≤x≤1; 0≤y≤1), (Ba_{1-x-y}SrₓCa_{y})Mg₃SiN₄:Eu²⁺ (0≤x1; 0≤y≤1).

For example, it is possible to combine several different phosphors or phosphor particles.

According to at least one embodiment of the method or the optoelectronic component, the functional layer comprises a reflective layer. The reflective layer is used to adjust the degree of transmission of the primary radiation of the semiconductor chip. Preferably, the reflective layer has a matrix material into which reflective particles are introduced. The reflective particles are preferably selected from the following group: TiO₂, SiO₂, ZrO₂, Al₂O₃, BaTiO₃, SrMiO₃, TCO (transparent conductive oxides), Nb₂O₅, HfO₂, ZnO. Particularly preferred, the reflective layer comprises TiO₂ or ZrO₂ or a combination thereof. The reflective particles, for example TiO₂ or ZrO₂, can be introduced into the reflective layer in the form of particles or the reflective layer consists of, for example, TiO₂ or ZrO₂.

According to at least one embodiment of the optoelectronic component, the semiconductor chip is a side-emitting semiconductor chip. In particular, in this embodiment, the functional layer comprises or consists of the reflective layer.

According to at least one embodiment of the method or the optoelectronic component, the semiconductor chips are side-emitting semiconductor chips and the functional layer comprises TiO₂ or ZrO₂ or consists of TiO₂ or ZrO₂. In particular, the functional layer can also comprise TiO₂ or ZrO₂ particles at the same time. It is advantageous to apply a defined thickness of the functional layer with TiO₂ and/or ZrO₂ in order to adjust the degree of partial transmission. The thickness of the functional layer with TiO₂ and/or ZrO₂ can be adjusted via the depth of the recesses. The depth of the recesses subsequently defines the thickness and thus the transmission of the functional layer with TiO₂ and/or ZrO₂.

One idea of the present method for producing an optoelectronic component is to dispense with measuring the position of the semiconductor chips on the carrier. The time-consuming AOI and LDI steps can be omitted by exposing over the entire surface. Exposure preferably takes place over the entire surface and the semiconductor chip itself is used to define the areas to be freely developed later. This method reduces the complexity of the process chain. In addition, the production costs of the method are reduced and the processes are stabilized, as there is no need for position measurement of the semiconductor chips and adjusted LDI exposure.

In this method, the semiconductor chips serve as an exposure mask for the unexposed parts of the photo-exposable material. The position of the semiconductor chips is therefore irrelevant and the method is self-adjusting. As a result, the requirement for placement accuracy of the semiconductor chips on the carrier is also lower.

### BRIEF DESCRIPTION OF THE DRAWINGS

Further advantageous embodiments and further embodiments of the method for producing an optoelectronic component and of the optoelectronic component result from the exemplary embodiment described below in conjunction with the figures.

FIGS. 1A to 1G and FIGS. 2A to 2E show schematic sectional views of various method stages of a method for producing an optoelectronic component according to one exemplary embodiment in each case.

FIG. 3 shows is a schematic sectional view of an optoelectronic component according to an exemplary embodiment.

Elements that are identical, similar or have the same effect are marked with the same reference signs in the figures. The figures and the proportions of the elements shown in the figures are not to be regarded as true to scale. Rather, individual elements, in particular layer thicknesses, may be shown in exaggerated size for better visualization and/or understanding.

For the sake of clarity, not all elements are marked with a reference sign.

### DETAILED DESCRIPTION OF ILLUSTRATIVE EMBODIMENTS

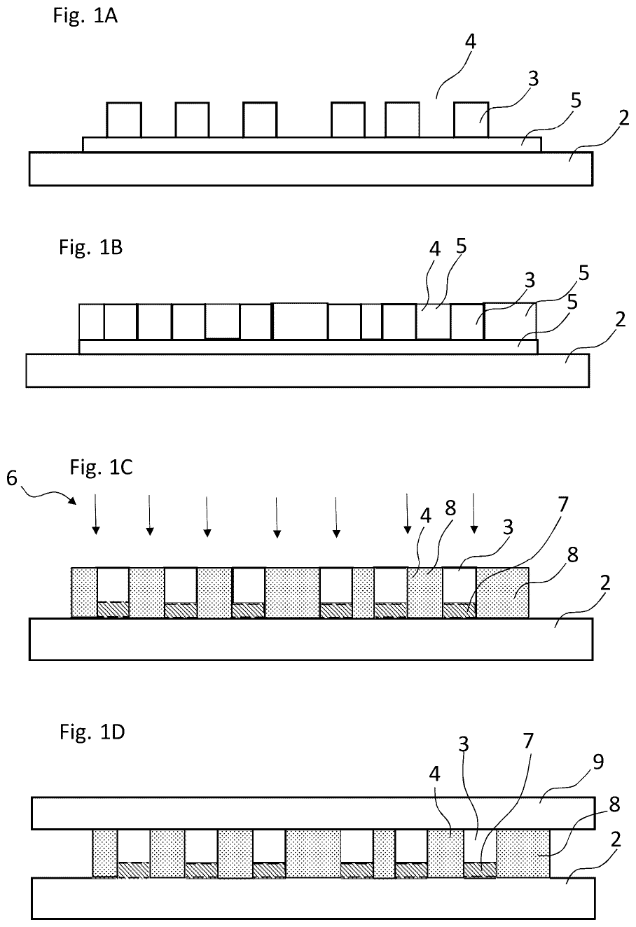

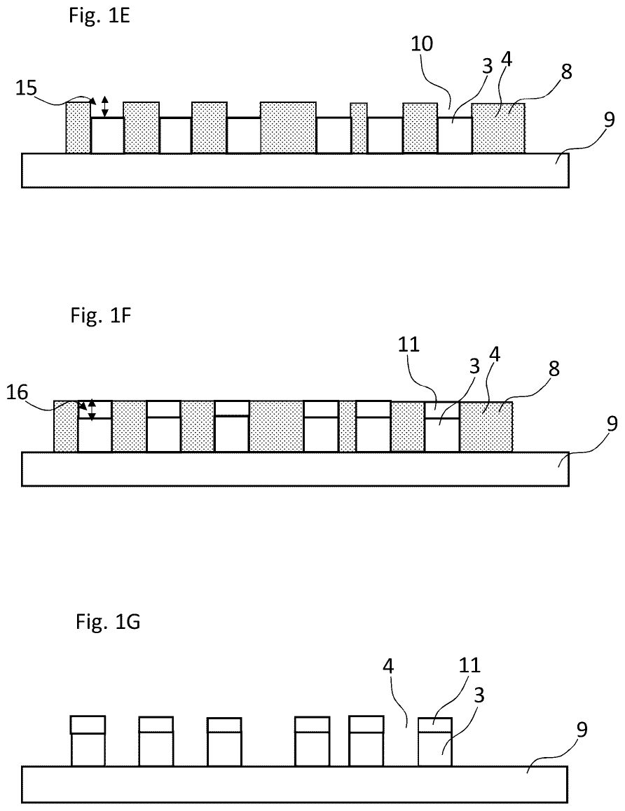

In the method for producing an optoelectronic component 1 according to the exemplary embodiment of FIGS. 1A to 1F, a carrier 2 is provided in a first step, see FIG. 1A. The carrier 2 is, for example, a wafer or a substrate, which is rectangular in shape.

In the next step, a photo-exposable material 5 is applied to the carrier 2. The photo-exposable material 5 is applied as a layer to the carrier 2. The photo-exposable material 5 is formed, for example, from a polymer which has a photoinitiator. For example, during exposure 6 or irradiation with electromagnetic radiation of a certain wavelength, the photoinitiator causes a crosslinking reaction and thus causes the polymer to cure or the photo-exposable material to cure. The photo-exposable material 5 is a negative resist. The photo-exposable material 5, which is arranged as a layer between the carrier 2 and the semiconductor chips 3, is applied as a dry resist or wet resist, preferably as a dry resist.

In a next step, a plurality of semiconductor chips 3 is applied to the photo-exposable material 5, the semiconductor chips 3 being applied spaced apart from one another in such a way that cavities 4 are formed between the semiconductor chips 3. The semiconductor chips 3 are set up to emit primary radiation of a first wavelength range during operation. The cavities 4 extend up to the photo-exposable material 5, which is arranged between the semiconductor chips 3 and the carrier 2. In particular, between 100 and 10000 semiconductor chips 3 are applied to the carrier 2. The number of semiconductor chips 3 depends on the size of the carrier 2, on the size of the semiconductor chips 3 and on the distance between the semiconductor chips 3.

In a next step, FIG. 1B, a photo-exposable material 5 is introduced, wherein at least the cavities 4 are filled with the photo-exposable material 5. The photo-exposable material 5, which is located in the cavities 4, preferably has the same material as the photo-exposable material 5, which is applied as a layer between the semiconductor chips 3 and the carrier 2.

The photo-exposable material 5, which is located in the cavities 4, is flush with the semiconductor chips 3 at the top surface of the semiconductor chips 3. The photo-exposable material 5 is preferably a wet resist. The thickness of the photo-exposable material 5 can be adjusted by spin coating, i.e. via the rotational speed. In addition, the cavities 4 can be filled with the photo-exposable material 5 using the inkjet method. In this case, preferably only the cavities 4 are filled with the photo-exposable material 5.

In FIG. 1C, the photo-exposable material 5 is exposed, wherein parts of the photo-exposable material 7, which are downstream of the semiconductor chips 3 in relation to the exposure 6, remain unexposed. Exposure 6 is carried out from the side facing the semiconductor chips 3. Exposure 6 hardens the photo-exposable material 8 in the cavities 4 and the photo-exposable material 7, which is located between the semiconductor chip 3 and the carrier 2, i.e. arranged downstream of the exposure 6, remains unexposed and therefore does not harden. Exposure 6 is preferably carried out using flood exposure in the UV range. Furthermore, the exposure 6 is over the entire surface and is self-adjusting. This has the advantage that the position of the semiconductor chips 3 is irrelevant, as the semiconductor chips 3 themselves serve as an exposure mask for the exposure 6. Optionally, the exposure 6 can also be carried out selectively.

In the next step, FIG. 1D, an auxiliary carrier 9 is placed on the side of the semiconductor chips 3 facing away from the carrier 2 after exposure and the carrier 2 is removed. This allows the semiconductor chips 3 to be in direct contact with the auxiliary carrier 9. The opposite side of the semiconductor chips 3, which is not on the auxiliary carrier 9, has the unexposed photo-exposable material 7 on its surface. This process is also referred to as turning, retaping or rebonding.

In FIG. 1E, the unexposed part of the photo-exposable material 7 is removed. This forms recesses 10. The recesses 10 have a depth 15. The unexposed part of the photo-exposable material 7 is removed by the method of developing. An alkaline medium is applied in this process. The recesses 10 are located on the semiconductor chips 3.

In FIG. 1F, a functional layer 11 is applied to the semiconductor chips 3. The functional layer 11 can, for example, be a conversion layer or a reflection layer. A reflective layer is advantageous if the semiconductor chip 3 is a side-emitting semiconductor chip 3. The functional layer 11 has a thickness of up to 20 μm. The recesses 10 are at least partially filled by the functional layer 11. In particular, the recesses 10 are completely filled by the functional layer 11. Furthermore, the functional layer 11 has a thickness 16 and the recess 10 has a depth 15. The thickness 16 of the functional layer 11 corresponds at most to the depth 15 of the recess 10.

In a further step, FIG. 1G, the exposed photo-exposable material 8, which is located in the cavities 4, is removed. This is done in an alkaline medium or in a solvent.

The semiconductor chips 3 with the functional layer 11 can then be singulated by removing them from the auxiliary carrier 9 and placing them at a desired location. Alternatively, the auxiliary carrier 9 can be divided so that the auxiliary carrier 9, the semiconductor chip 3 and the functional layer 11 remain as optoelectronic component 1.

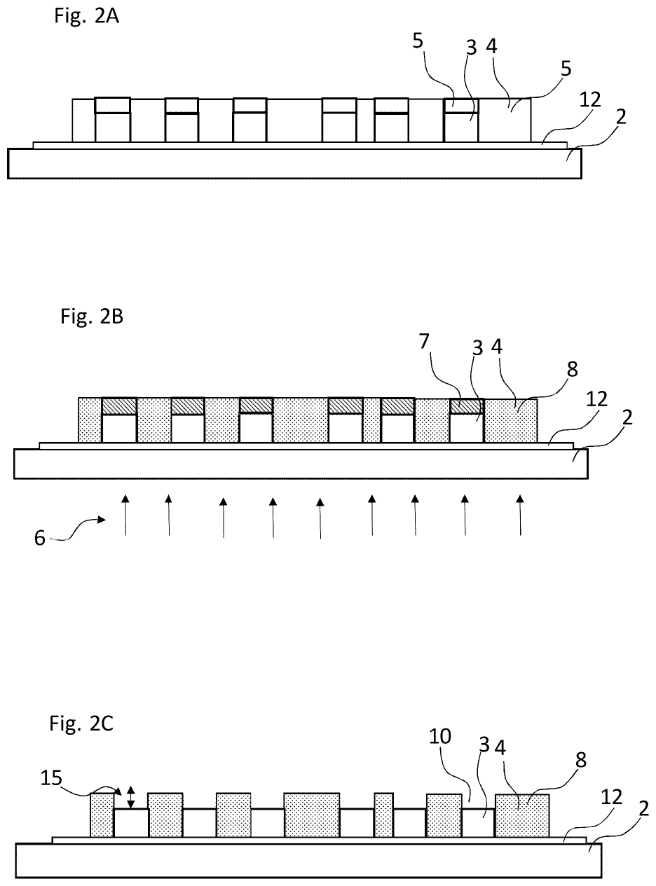

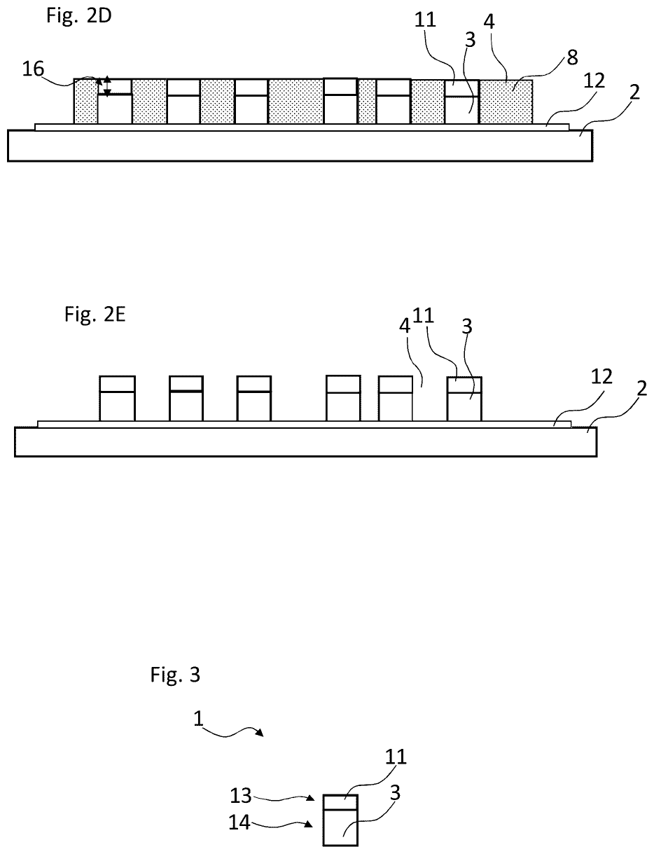

In the method of the exemplary embodiment 2 according to FIGS. 2A to 2E, a carrier 2 is first provided, see FIG. 2A. An adhesive layer 12 is arranged on the carrier 2. The adhesive layer 12 and the carrier 2 are designed to be radiation permeable to the radiation of an exposure wavelength. Exposure is preferably carried out using a UV light source. Subsequently, a plurality of semiconductor chips 3 are arranged on the adhesive layer 12, the semiconductor chips 3 being applied spaced apart from one another in such a way that cavities 4 are formed between the semiconductor chips 3. A photo-exposable material 5 is introduced, at least the cavities 4 being filled with the photo-exposable material 5.

On the one hand, the cavities 4 and the area above the semiconductor chips 3 can be filled with the photo-exposable material 5 in one step. Alternatively, a two-step method can be used. In this case, the photo-exposable material 5 is first introduced into the cavities 4. The photo-exposable material 5 in the cavities 4 and the semiconductor chips 3 are flush with each other at their surface. In a second step, a dry resist is then applied to the photo-exposable material 5 in the cavities 4 and to the semiconductor chips 3 as a preferably continuous layer. A wet resist is preferably used as the photo-exposable material 5 in the first step.

The advantage of the two-stage method is that the dry resist can be applied as a predefined, very homogeneous layer to the semiconductor chip 3 and to the cavities 4 filled with photo-exposable material 5, whereas the wet resist can form significantly greater inhomogeneities by spinning over the set semiconductor chips, which would impair the light extraction of the optoelectronic component 1.

In a next step, FIG. 2B, exposure 6 of the photo-exposable material 5 takes place, wherein parts of the photo-exposable material 7, which are downstream of the semiconductor chips 3 with respect to the exposure 6, remain unexposed. The exposure 6 takes place through the carrier 2 and through the adhesive layer 12, so that the part of the photo-exposable material 7 which is located on the semiconductor chips 3 remains unexposed. The photo-exposable material 8 in the cavities 4 is exposed and hardens.

FIG. 2C shows that the unexposed parts of the photo-exposable material 7 have been removed. As a result, recesses 10 are formed. These recesses 10 have the same depth 15 as the thickness of the unexposed part of the photo-exposable material 7.

In a next step, FIG. 2D, a functional layer 11 is applied to the semiconductor chips 3. The functional layer 11 is, for example, a conversion layer or a reflection layer. If the semiconductor chip 3 is a side-emitting semiconductor chip 3, the functional layer 11 comprises TiO₂ and/or ZrO₂. The functional layer 11 has a thickness 16 and the recess 10 has a depth 15, wherein the thickness 16 of the functional layer 11 corresponds at most to the depth 15 of the recess 10.

In FIG. 2E, the exposed photo-exposable material 8 in the cavities 4 is removed. The removal is carried out using solvents and/or in an alkaline medium.

The exemplary embodiment of FIG. 3 shows a semiconductor chip 3 which emits primary radiation of a first wavelength range during operation, a functional layer 11 arranged on the semiconductor chip 3, and a side surface of the functional layer 13 and a side surface of the semiconductor chip 14 which are flush with each other. The functional layer 11 is arranged in direct contact with the semiconductor chip 3. The side surfaces of the functional layer 13 and the side surfaces of the semiconductor chip 14 are free of traces of a singulation process. The functional layer 11 has a thickness of between 5 micrometers inclusive and 120 micrometers inclusive. Preferably, the functional layer 11 has a thickness of up to 20 μm. In addition, the functional layer 11 comprises a conversion layer or a reflection layer. In the case of side-emitting semiconductor chips 3, a reflective layer is preferably used. The conversion layer has a matrix in which phosphor particles are embedded. The reflective layer has a matrix material in which reflective particles are embedded. The reflective particles are preferably selected from the following group: TiO₂, SiO₂, ZrO₂, Al₂O₃, BaTiO₃, SrTiO₃, TCO (transparent conductive oxides), Nb₂O₅, HfO₂, ZnO.

The features and exemplary embodiments described in connection with the figures can be combined with one another in accordance with further embodiments, even if not all combinations are explicitly described. Furthermore, the exemplary embodiments described in connection with the figures may alternatively or additionally have further features as described in the general part.

The invention is not limited to the description based on the exemplary embodiments. Rather, the invention includes any new feature as well as any combination of features, which includes in particular any combination of features in the patent claims, even if this feature or combination itself is not explicitly stated in the patent claims or exemplary embodiments.

1.-19. (canceled)

20. A method for producing an optoelectronic component, the method comprising:
providing a carrier;
applying a plurality of semiconductor chips to the carrier, the semiconductor chips being spaced apart from one another such that cavities are formed between the semiconductor chips;
introducing a photo-exposable material, at least the cavities being filled with the photo-exposable material;
exposing the photo-exposable material, wherein parts of the photo-exposable material, which are downstream of the semiconductor chips with respect to an exposure remain unexposed;
removing unexposed parts of the photo-exposable material, wherein recesses are formed;
applying a functional layer to the semiconductor chips; and
removing the exposed photo-exposable material.

21. The method according to claim 20, wherein the recesses are at least partially filled by the functional layer.

22. The method according to claim 20, wherein the exposure is carried out selectively.

23. The method according to claim 20, wherein the exposure is carried out over an entire surface and in a self-adjusting manner.

24. The method according to claim 20, wherein the photo-exposable material is a negative resist.

25. The method according to claim 20, wherein the functional layer has a thickness and the recesses have a depth, and wherein the thickness of the functional layer corresponds at most to the depth of the recesses.

26. The method according to claim 20, further comprising:
prior to applying of the plurality of semiconductor chips to the carrier, applying a part of the photo-exposable material between the carrier and the semiconductor chips,
wherein the exposure is carried out from a side of the semiconductor chips, which is free of the photo-exposable material.

27. The method according to the claim 26, wherein the part of the photo-exposable material, which is located between the carrier and the semiconductor chips, is a wet resist or a dry resist, and wherein the photo-exposable material, which is located in the cavities, is a wet resist.

28. The method according to claim 20, further comprising:
after the exposure, arranging an auxiliary carrier on a side of the semiconductor chips facing away from the carrier; and
removing the carrier.

29. The method according to claim 20, wherein the carrier is radiation permeable.

30. The method according to claim 20, further comprising:
arranging an adhesive layer between the carrier and the plurality of semiconductor chips.

31. The method according to claim 20, wherein the exposure takes place through the carrier so that the part of the photo-exposable material, which is located on the semiconductor chips, remains unexposed.

32. The method according to claim 20, further comprising:
after removing the exposed photo-exposable material, singulating the semiconductor chips.

33. The method according to claim 20, wherein the functional layer comprises a conversion layer.

34. The method according to claim 20, wherein the functional layer comprises a reflective layer.

35. An optoelectronic component comprising:
a side-emitting semiconductor chip configured to emit primary radiation of a first wavelength range;
a functional layer arranged on the side-emitting semiconductor chip; and
side surfaces of the functional layer and side surfaces of the side-emitting semiconductor chip are flush with each other.

36. The optoelectronic component according to claim 35, wherein the functional layer has a thickness of up to 20 micrometers.

37. The optoelectronic component according to claim 35, wherein the functional layer comprises a conversion layer.

38. The optoelectronic component according to claim 35, wherein the functional layer comprises a reflective layer.

39. The optoelectronic component according to claim 35, wherein the functional layer comprises TiO₂ or consists of TiO₂.
